(19) United States
(12) Patent Application Publication
(10) Pub. No.: US 2007/0132371 A1
(43) Pub. Date: Jun. 14, 2007

(54) Color tunable light-emitting devices and method of making the same

(75) Inventor: Jie Liu, Niskayuna, NY (US)

Correspondence Address: Andrew J. Caruso;General Electric Global Research, Docket Room K1-4A59, One Research Circle, Niskayuna, NY, 12309, US

(73) Assignee: General Electric Company, Schenectady, NY (US)

(21) Appl. No.: 11/301,167

(22) Filed: Dec. 12, 2005

(51) Int. Cl. H01L 51/00

(52) U.S. Cl. 313/504

(57) ABSTRACT

A color tunable light-emitting device comprising a first light-emitting element, a passive light transformative element, an active light transformative element (e.g. an electrochromic element) disposed between the first light-emitting element and the passive light transformative element; and at least one light transmissive element. Active light transformative elements which may be employed are illustrated by electrochromic elements, photochromic elements, and thermochromic elements.

### STATEMENT REGARDING FEDERALLY SPONSORED RESEARCH & DEVELOPMENT

This invention was made with Government support under contract number 70NANB3H3030 awarded by NIST. The Government has certain rights in the invention.

### BACKGROUND

The invention relates generally to color tunable light-emitting devices. More particularly the invention relates to color tunable organic light-emitting devices. Organic light-emitting devices (OLEDs) have attracted extensive research and development efforts due to their potential applications for flat panel display and general illumination. Currently available devices or models are mainly focused on devices with a fixed color, either intrinsic color emitted by the OLEDs or an arbitrarily produced color by various color conversion techniques, such as by making a stack of red, and/or green, and/or blue light-emitting devices, using extra photoluminescent layers.

However, for certain applications, such as interior/exterior decorations, and signage, improvements in color tunability are desirable. Thus, there is a need for color tunable light-emitting devices exhibiting enhanced control of the color of the light emerging from the device.

### BRIEF DESCRIPTION

In accordance with the aspects of the present invention, a color tunable light-emitting device is presented. In one embodiment the color tunable light-emitting device comprises a first light-emitting element, a passive light transformative element, an active light transformative element disposed between said first light-emitting element and said passive light transformative element; and at least one light transmissive element.

In another embodiment a color tunable light-emitting device comprises a first light-emitting element, a passive light transformative element, an electrochromic element disposed between said first light-emitting element and said passive light transformative element, and at least one light transmissive element

In another embodiment a color tunable light-emitting device comprises a first light-emitting element, a passive light transformative element, a photochromic element disposed between said first light-emitting element and said passive light transformative element, and at least one light transmissive element.

In yet another embodiment a color tunable light-emitting device comprises a first light-emitting element, a passive light transformative element, a thermochromic element disposed between said first light-emitting element and said passive light transformative element, and at least one light transmissive element,.

According to further aspects of the present invention, a method of fabricating a color tunable light-emitting device is presented.

### DRAWINGS

These and other features, aspects, and advantages of the present invention will become better understood when the following detailed description is read with reference to the accompanying drawings in which like characters represent like parts throughout the drawings, wherein:

FIG. 1 is a schematic representation of an exemplary embodiment of a color tunable light-emitting device, according to aspects of the present invention;

FIG. 2 is a cross-sectional representation of an exemplary embodiment of a color tunable light-emitting device, according to aspects of the present invention;

FIG. 3 is a schematic representation of an exemplary embodiment of a color tunable light-emitting device, according to aspects of the present invention;

FIG. 4 is a cross-sectional representation of an exemplary embodiment of a color tunable light-emitting device, according to aspects of the present invention;

FIG. 5 is a schematic representation of an exemplary embodiment of a color tunable light-emitting device, according to aspects of the present invention;

FIG. 6 is a schematic representation of an exemplary embodiment of a color tunable light-emitting device, according to aspects of the present invention;

FIG. 7 is a cross-sectional representation of an exemplary embodiment of a color tunable light-emitting device, according to aspects of the present invention

FIG. 8 is a cross-sectional representation of an exemplary embodiment of a color tunable light-emitting device, according to aspects of the present invention

FIG. 9 is a representation of exemplary OLED structure;

FIG. 10 is a representation of the current-density and brightness as a function of bias voltage of an ADS329-based OLED;

FIG. 11 is a flow chart illustrating an exemplary process of fabricating the color tunable light-emitting device according to aspects of the present invention;

FIG. 12 is a schematic representation of an electrochromic element.

In the following specification and the claims, which follow, reference will be made to a number of terms, which shall be defined to have the following meanings. The singular forms “a”, “an” and “the” include plural referents unless the context clearly dictates otherwise.

As used herein, the term “disposed over” or “deposited over” or “disposed between” refers to disposed or deposited immediately on top of and in contact with, or disposed or deposited on top of but with intervening layers there between.

The term “alkyl” as used in the various embodiments of the present invention is intended to designate linear alkyl, branched alkyl, aralkyl, cycloalkyl, bicycloalkyl, tricycloalkyl and polycycloalkyl radicals comprising carbon and hydrogen atoms, and optionally containing atoms in addition to carbon and hydrogen, for example atoms selected from Groups 15, 16 and 17 of the Periodic Table. Alkyl groups may be saturated or unsaturated, and may comprise, for example, vinyl or allyl. The term “alkyl” also encompasses that alkyl portion of alkoxide groups. Unless otherwise noted, in various embodiments normal and branched alkyl radicals are those containing from 1 to about 32 carbon atoms, and comprise as illustrative non-limiting examples C₁-C₃₂ alkyl (optionally substituted with one or more groups selected from C₁-C₃₂ alkyl, C₃-C₁₅ cycloalkyl or aryl); and C₃-C₁₅ cycloalkyl optionally substituted with one or more groups selected from C₁-C₃₂ alkyl or aryl. Some illustrative, non-limiting examples comprise methyl, ethyl, n-propyl, isopropyl, n-butyl, sec-butyl, tertiary-butyl, pentyl, neopentyl, hexyl, heptyl, octyl, nonyl, decyl, undecyl and dodecyl. Some particular illustrative non-limiting examples of cycloalkyl and bicycloalkyl radicals comprise cyclobutyl, cyclopentyl, cyclohexyl, methylcyclohexyl, cycloheptyl, bicycloheptyl and adamantyl. In various embodiments aralkyl radicals comprise those containing from 7 to about 14 carbon atoms; these include, but are not limited to, benzyl, phenylbutyl, phenylpropyl, and phenylethyl. The term “aryl” as used in the various embodiments of the present invention is intended to designate substituted or unsubstituted aryl radicals comprising from 6 to 20 ring carbon atoms. Some illustrative non-limiting examples of aryl radicals include C₆-C₂₀ aryl optionally substituted with one or more groups selected from C₁-C₃₂ alkyl, C₃-C₁₅ cycloalkyl, aryl, and functional groups comprising atoms selected from Groups 15, 16 and 17 of the Periodic Table. Some particular illustrative, non-limiting examples of aryl radicals comprise substituted or unsubstituted phenyl, biphenyl, tolyl, xylyl, naphthyl and binaphthyl.

As used herein the term “substantially transparent” means allowing at least 50 percent, of light in the visible wavelength range to be transmitted through an article or component, typically a film having a thickness of about 0.5 micrometer or less, at an incident angle of less than or equal to 10 degrees.

In accordance with certain embodiments of the present invention, there is provided a color tunable light-emitting device. In one embodiment the color tunable light-emitting device comprises a first light-emitting element, a passive light transformative element, an active light transformative element selected from the group consisting of electrochromic elements, photochromic elements, thermochromic elements, and combinations of two or more of the foregoing, said active light transformative element being disposed between said first light-emitting element and said passive light transformative element; and at least one light transmissive element.

As used herein, electrochromic elements, photochromic elements, and thermochromic elements present in various embodiments of the color-tunable light-emitting devices of the present invention are defined to be “active” light transformative elements and are distinct from passive light transformative elements such as phosphors and color filters. Active light transformative elements modulate light passing through them in response to and as a function of an applied bias. In the case of electrochromic elements, the bias results from the application of a voltage differential within the electrochromic element. In the case of photochromic elements, the bias results from the irradiation of the photochromic element with a source of light. In the case of a thermochromic element, the bias results from the application of heat to (or the removal of heat from) the thermochromic element. Those skilled in the art will appreciate that since in each case the bias may be applied to a lesser or greater extent (i.e. the bias is tunable), the color emerging from the active light transformative element is tunable thereby. In certain embodiments, the light emerging from the color tunable light-emitting devices of the present invention will be modulated by the application of a predetermined bias, for example a specific voltage differential applied to an electrochromic element within a color tunable light-emitting device. In other instances, the bias is provided by the environment. For example, in the case of a photochromic element, the color emerging from a color tunable light-emitting device may be modulated by intentional changes in the level of ambient light or by an unintended change in the level of ambient light. An example of an intended change in the level of ambient light that may be given is the change in the level of ambient light that occurs as a theater or aircraft cabin is intentionally darkened. An example of an unintended change in the level of ambient light that may be given is the change in the level of ambient light that occurs as a dark cloud obscures the sun, or for that matter the change in the level of ambient light occasioned by the setting of the sun, a change anticipated though not necessarily intended. Similarly, in case of the thermochromic element, the change in color can be a result of an intentional change in temperature or may be a response to an unintended change in temperature. Such color tunable light-emitting devices may be used as a temperature indicator, signaling by a change in color whether something in thermal contact with the thermochromic element of the color tunable light-emitting device is cold, warm, or hot. The color tunable devices of the present invention comprise at least one passive light transformative element.

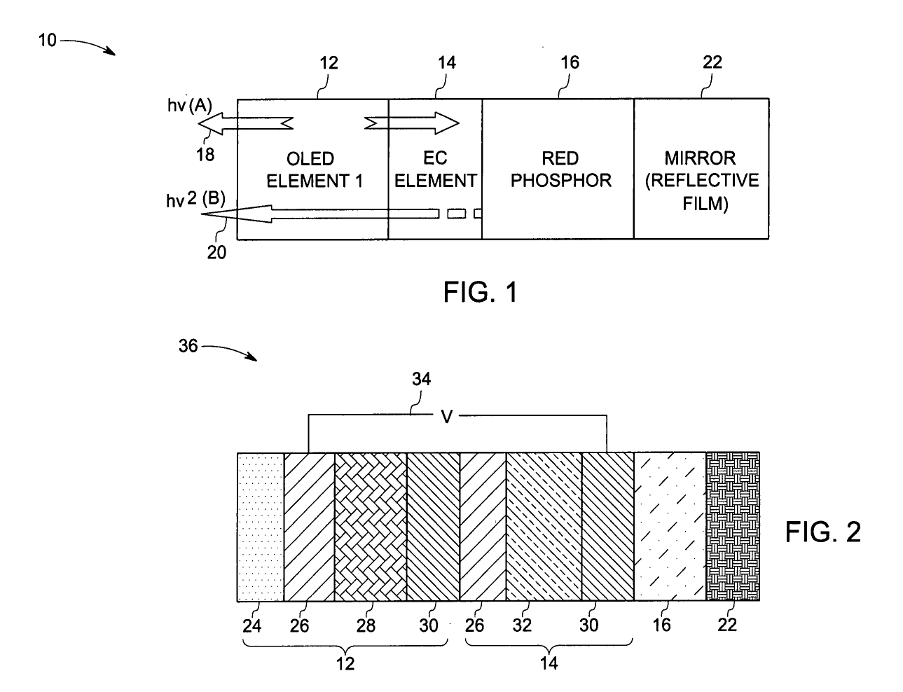

FIG. 1 illustrates an embodiment which is a color tunable light-emitting device (10) comprising an OLED (12), an active light transformative element, here an electrochromic element (14), a passive light transformative element, here a red phosphor layer (16), and a reflective mirror (22). The transmission properties of the electrochromic element (14) can be tuned by varying an applied voltage bias. The perceived color is thus a combination of the unmodulated light (18) emerging directly from the device and modulated light (20), said modulated light (20) being modulated by one or more of the light transformative elements (14) and (16). In another embodiment the electrochromic element is replaced with a photochromic element. When a photochromic element is used the photochromic element can be tuned by coupling with a tunable light source. In yet another embodiment, the electrochromic element is replaced with a thermochromic element. When a thermochromic element is used the thermochromic element can be tuned by coupling with a temperature tunable source.

FIG. 2 represents a cross-sectional view (36) of the color tunable light-emitting device (10) of FIG. 1. In this illustrated embodiment, a the color tunable light-emitting device is shown to include an OLED (12), the OLED comprising a first substrate (24), a first electrode (26), a first electroluminescent layer (28), and a second electrode (30), an electrochromic element (14), the electrochromic element comprising a third electrode (26), an electrochromophor layer (32), and a fourth electrode (30), a passive light transformative element (16), and a reflective mirror (22). The OLED and the electrochromic element are together connected to a single external tunable voltage source (34), indicating that two of the elements are electrically coupled and all elements discussed above i.e., the OLED, electrochromic element, the passive light transformative element, and the reflective mirror are optically coupled.

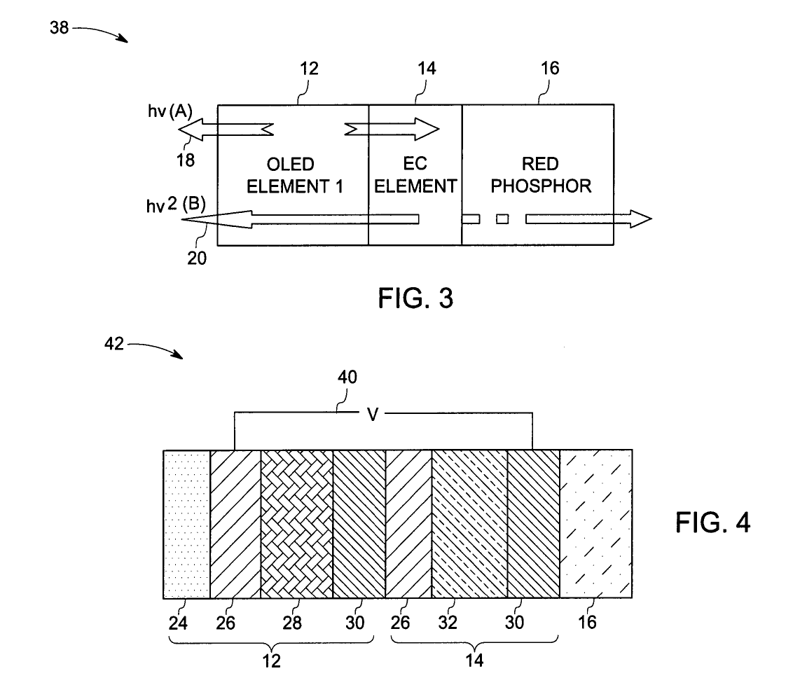

FIG. 3 illustrates an embodiment which is a color tunable light-emitting device (38) comprising an OLED (12), an active light transformative element which is an electrochromic element (14), and a passive light transformative element which is a red phosphor (16).; The transmission of the electrochromic element (14) can be tuned by varying an applied voltage bias. The perceived color is thus a combination of the unmodulated light (18) emerging directly from the device and modulated light (20), said modulated light (20) being modulated by one or more of the light transformative elements (14) and (16).

FIG. 4 represents a cross sectional view (42) of the color tunable light-emitting device (38) of FIG. 3. The color tunable light-emitting device comprises an organic light-emitting device (12), an electrochromic element (14), and a passive light transformative element (16). FIG. 4 also shows a power supply (40) which applies a voltage bias across both the organic light-emitting device (12) and the electrochromic element (14).

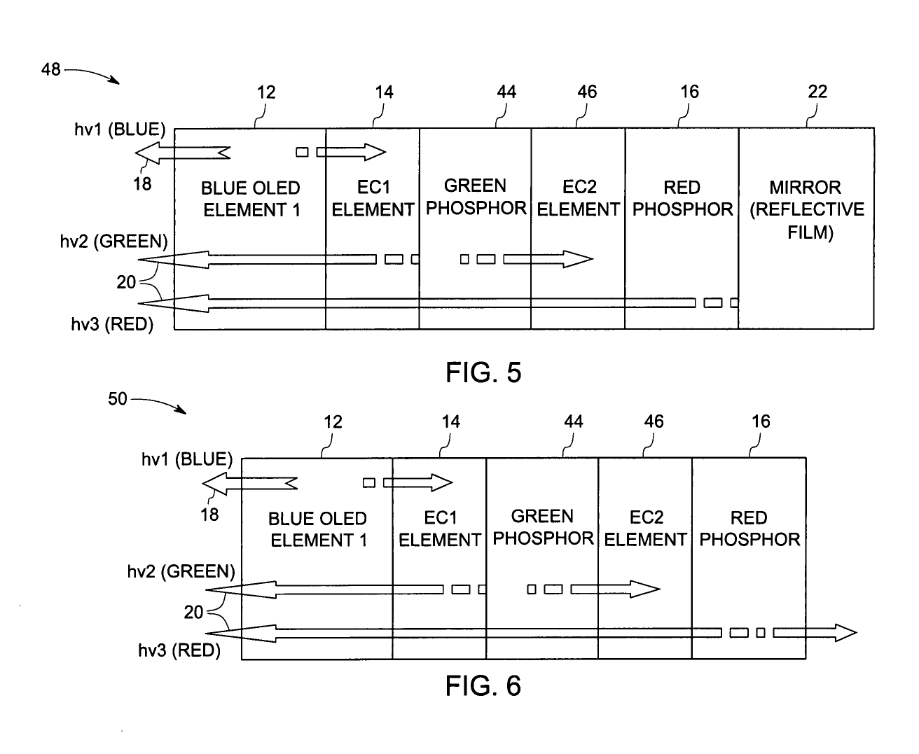

FIG. 5 illustrates an embodiment which is a color tunable light-emitting device (48) comprising an organic light-emitting device (12), a first passive light transformative element which is a red phosphor (16); a second passive light transformative element which is a green phosphor (44), a first electrochromic element (14), a second electrochromic element (46), and a mirror (22). The transmission of the electrochromic elements can be tuned by varying the applied voltage bias. The perceived color is thus a combination of the unmodulated light (18) emerging directly from the device and modulated light (20), said modulated light (20) being modulated by one or more of the light transformative elements (14), (44), (46), and (16). Green modulated light is indicated in FIG. 5 as “hv2”. Red modulated light is indicated in FIG. 5 as “hv3”.

FIG. 6 illustrates an embodiment which is a color tunable light-emitting device (50). Device (50) is very similar to that shown in FIG. 5 except that there is no mirror or reflective surface on one end.

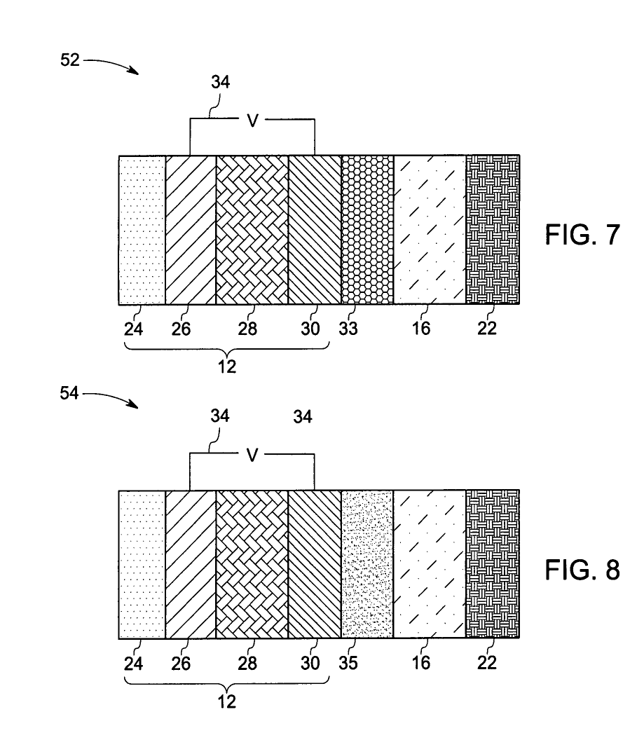

FIG. 7 illustrates an embodiment, shown in a cross-sectional view, which is a color tunable light-emitting device (52) comprising an OLED (12), a photochromic element (33), a passive light transformative element which is a red phosphor (16), a reflective mirror (22) and a power supply (34).

FIG. 8 illustrates an embodiment, shown in a cross-sectional view, which is a color tunable light-emitting device (54) comprising an OLED (12), a thermochromic element (35), a passive light transformative element which is a red phosphor (16), a reflective mirror (22), and a power supply (34).

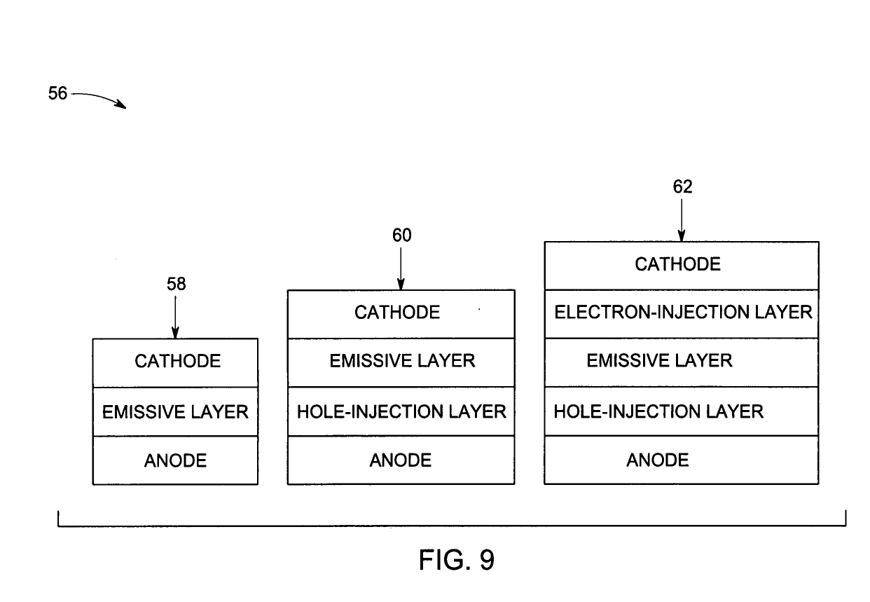

As noted, in one embodiment, the first light-emitting element of the color tunable light-emitting device of the present invention is an organic light emitting device (OLED). Suitable OLEDs (56) are illustrated in FIG. 9 and typically comprise an electroluminescent layer (hereinafter also referred to as an organic emissive layer or light-emitting layer) sandwiched between two electrodes (the anode and the cathode), for example, as shown in FIG. 9 in each of the exemplary OLEDs (58), (60), and (62). Furthermore, the electroluminescent layer can be configured in a variety of ways, as for example, (a) a single layer configuration (58) wherein the single layer organic semiconductor provides efficient hole injection/transport, emission, electron injection or transport functions; (b) a bilayer configuration (60) wherein a separate layer, in addition to the emitting layer, serves as a hole-injection (or electron-injection) layer; and (c) a trilayer configuration (62) wherein the device comprises a separate hole-injection layer and a separate electron-injection layer, in addition to the emissive layer. Furthermore, it should be noted that for each configuration, one or more additional layers may be present to provide, for example, charge blocking or confinement functions, if needed.

The anode represented in various figures as the electrode (26) usually comprises a material having a high work function; e.g., greater than about 4.0 eV, for example from about 5 eV to about 7 eV. Transparent metal oxides, such as indium tin oxide (“ITO”), are typically used for this purpose. ITO is substantially transparent to light transmission and allows light emitted from organic emissive layer easily to escape through the ITO anode layer without being seriously attenuated. Other materials suitable for use as the anode layer are tin oxide, indium oxide, zinc oxide, indium zinc oxide, zinc indium tin oxide, antimony oxide, and mixtures thereof. The anode layer may be deposited on the underlying element by a variety of techniques including physical vapor deposition, chemical vapor deposition, and or sputtering. The thickness of an anode comprising such an electrically conducting oxide can be in the range from about 10 nanometers (nm) to about 500 nm, specifically from about 10 nm to about 200 nm, and more specifically from about 50 nm to about 200 nm. In certain embodiments, a thin, substantially transparent layer of a metal is also suitable; for example, a layer of a metal having a thickness less than about 50 nm, specifically less than about 20 nm. Suitable metals for the anode include, for example, silver, copper, tungsten, nickel, cobalt, iron, selenium, germanium, gold, platinum, aluminum, or mixtures thereof or alloys thereof.

The cathode represented in various figures as the electrode (30) injects negative charge carriers (electrons) into the organic emissive layer and is typically made of a material having a low work function; e.g., less than about 4 eV. Those skilled in the art will appreciate, however that not every material suitable for use as the cathode, need to have a low work function. Materials suitable for use as the cathode include K, Li, Na, Mg, Ca, Sr, Ba, Al, Ag, In, Sn, Zn, Zr, Sc, Y, elements of the lanthanide series, alloys thereof, or mixtures thereof. Suitable alloy materials for the manufacture of cathode layer are Ag—Mg, Al—Li, In—Mg, and Al—Ca alloys. Layered non-alloy structures are also possible, such as a thin layer of a metal such as Ca (thickness from about 1 to about 50 nm) or a non-metal such as LiF, KF, or NaF, over-capped by a thicker layer of some other metal, such as aluminum or silver. The cathode may be deposited on the underlying layer by, for example, physical vapor deposition, chemical vapor deposition, or sputtering. Depending on the application, the cathode can be transparent/semitransparent (such as ITO, a thin layer of metal over-capped with ITO), or opaque (such as thick metal layers).

Electroluminiscent (EL) materials generally refer to organic fluorescent and/or phosphorescent materials, which emit light when subjected to an applied voltage bias. Electroluminiscent materials may be tailored to emit light in the desired wavelength range. The thickness of the electroluminiscent layer is preferably kept in the range of about 40 nm to about 300 nm. The electroluminiscent material may be a polymer, a copolymer, a mixture of polymers, or a lower molecular weight organic molecule having unsaturated bonds. Numerous electroluminescent materials are disclosed in “Advanced Materials 2000 12 (23) 1737-1750”. Non-limiting examples of electroluminescent materials which may be used include poly(N-vinylcarbazole) (PVK) and its derivatives; polyfluorene and its derivatives such as poly(alkylfluorene), for example poly(9,9-dihexylfluorene), poly(dioctylfluorene) or poly(9,9-bis(3,6-dioxaheptyl)-fluorene-2,7-diyl), poly(para-phenylene) (PPP) and its derivatives such as poly(2-decyloxy-1,4-phenylene) or poly(2,5-diheptyl-1,4-phenylene); poly(p-phenylene vinylene) (PPV) and its derivatives such as dialkoxy-substituted PPV and cyano-substituted PPV; polythiophene and its derivatives such as poly(3-alkylthiophene), poly(4,4′-dialkyl-2,2′-bithiophene), poly(2,5-thienylene vinylene); poly(pyridine vinylene) and its derivatives; polyquinoxaline and its derivatives; and polyquinoline and its derivatives. In one particular embodiment, a suitable electroluminescent material is poly(9,9-dioctylfluorenyl-2,7-diyl) end capped with N,N-bis(4-methylphenyl)-4-aniline. Mixtures of these polymers or copolymers based on one or more of these polymers and others may also be used.

As noted, another class of suitable materials used as electroluminescent materials are the polysilanes. Typically, polysilanes are linear polymers having a silicon-backbone substituted with a variety of alkyl and/or aryl side groups. Polysilanes are quasi one-dimensional materials with delocalized sigma-conjugated electrons along the polymer backbone. Examples of polysilanes comprise poly(di-n-butylsilane), poly(di-n-pentylsilane), poly(di-n-hexylsilane), poly(methylphenylsilane), and poly(bis(p-butylphenyl)silane).

Organic materials having weight average molecular weight less than, for example, about 5000 grams per mole comprising aromatic units are also applicable as electroluminiscent materials. An example of such materials is 1,3,5-tris(N-(4-diphenylaminophenyl)phenylamino)benzene, which emits light in the wavelength range of 380-500 nm. The organic EL layer also may be prepared from lower molecular weight organic molecules, such as phenylanthracene, tetraarylethene, coumarin, rubrene, tetraphenylbutadiene, anthracene, perylene, coronene, or their derivatives. These materials generally emit light having a maximum wavelength of about 520 nm. Still other suitable materials are the low molecular-weight metal organic complexes such as aluminum-, gallium-, and indium-acetylacetonate, which emit light in the wavelength range of 415-457 nm, aluminum-(picolymethylketone)-bis(2,6-di(t-butyl)phenoxide) or scandium-(4-methoxy-picolylmethylketone)-bis(acetylacetonate), which emit in the range of 420-433 nm. In certain white light applications, the preferred electroluminiscent materials are those that emit light in the blue-green wavelengths. Other suitable electroluminiscent materials that emit in the visible wavelength range are organo-metallic complexes of 8-hydroxyquinoline, such as tris(8-quinolinolato)aluminum and its derivatives. Other non-limiting examples of electroluminiscent materials are disclosed in U. Mitschke and P. Bauerle, “The Electroluminescence of Organic Materials, J. Mater. Chem., Vol. 10, pp. 1471-1507 (2000)”.

As described above, the OLEDs may further include one or more layers such as a charge transport layer, hole transport layer, a hole injection layer, a hole injection enhancement layer an electron transport layer, an electron injection layer and an electron injection enhancement layer or any combination thereof. The OLEDs may further include a substrate layer such as, but not limited to, a polymeric substrate.

Materials suitable for use as charge transport layers typically include low-to-intermediate molecular weight organic polymers (for example, organic polymers having weight average molecular weights (M_{w}) of less than about 200,000 grams per mole) for example, poly(3,4-ethylenedioxythiophene) (PEDOT), polyaniline, poly(3,4-propylenedioxythiophene) (PProDOT), polystyrenesulfonate (PSS), polyvinyl carbazole (PVK), and like materials

Examples of materials suitable for the hole transport layer include triaryldiamines, tetraphenyldiamines, aromatic tertiary amines, hydrazone derivatives, carbazole derivatives, triazole derivatives, imidazole derivatives, oxadiazole derivatives comprising an amino group, polythiophenes, and like materials. Suitable materials for a hole-blocking layer comprise poly(N-vinyl carbazole), and like materials.

Materials suitable for the hole-injection layer are known to those skilled in the art and include “p-doped” (proton-doped) conducting polymers, such as proton-doped polythiophene or polyaniline, and p-doped organic semiconductors, such as tetrafluorotetracyanoquinodimethane (F4-TCQN), doped organic and polymeric semiconductors, and triarylamine-containing compounds and polymers. Suitable electron-injection materials are also known to those skilled in the art and include polyfluorene and its derivatives, aluminum tris (8-hydroxyquinoline) (Alq3), organic/polymeric semiconductors n-doped with alkali (alkaline earth) metals, and the like.

Examples of materials suitable for the hole injection enhancement layer include arylene-based compounds such as 3,4,9,10-perylenetetra-carboxylic dianhydride, bis(1,2,5-thiadiazolo)-p-quinobis(1,3-dithiole), and like materials.

Examples of materials suitable for the electron injection enhancement layer materials and electron transport layer materials include metal organic complexes such as oxadiazole derivatives, perylene derivatives, pyridine derivatives, pyrimidine derivatives, quinoline derivatives, quinoxaline derivatives, diphenylquinone derivatives, nitro-substituted fluorene derivatives, and like materials.

Typically, the OLED comprises one or two substrates selected from rigid substrates and flexible substrates. The rigid substrates include but are not limited to glass, metal and plastic; and the flexible substrates include but are not limited to flexible glass, metal foil, and plastic films. Non-limiting examples of substrates include thermoplastic polymers (for example, poly(ethylene terephthalate), poly(ethylene naphthalate), polyethersulfones, polycarbonates, polyimides, polyacrylates, polyolefins), glass, metal, and combinations thereof. The at least one light transmissive element, which forms a part of the color tunable light-emitting device is typically a separate substrate layer or a substrate comprised in an OLED, as described above.

As noted, passive light transformative elements employed in the color tunable light-emitting devices are illustrated by color filters and phosphors. A color filter is typically comprises a sheet of dyed glass, gelatin, or plastic which absorbs certain colors and permits better rendition of others. Color filters are well known to those skilled in the art.

Phosphors illustrate another type of passive light transformative element. A phosphor exhibits the phenomenon of phosphorescence. Phosphorescence may be defined as sustained light emission following an initial exposure to light. This is sometimes referred to as “glowing without further stimulus”. Phosphors are well known to those skilled in the art and are typically transition metal compounds or rare earth compounds of various types. The term “transition metal” more commonly refers to any element in the d-block of the periodic table, including zinc and scandium. This corresponds to periodic table groups 3 to 12 inclusive. Compounds of the “inner transition elements” from the lanthanide and actinide series where the inner f orbital is filled as atomic number increases may also be used as the phosphor. The inner transition elements are made up of the elements from cerium (At. No. 58) to lutetium (At. No. 71) and thorium (At. No. 90) to Lawrencium (At. No. 103). Rare earth compounds are typically oxides of the elements in the lanthanide series that include actinium, thorium, protactinium, uranium, neptunium, plutonium, americium, curium, berkelium, californium, einsteinium, fermium, mendelevium, nobelium and lawrencium.

The color tunable light-emitting devices of the present invention may include additional layers such as, but not limited to, one or more of an abrasion resistant layer, an adhesion layer, a chemically resistant layer, a photoluminescent layer, a radiation-absorbing layer, a radiation reflective layer, a barrier layer, a planarizing layer, an optical diffusing layer, and combinations thereof.

Examples of suitable electrochromic materials are, inorganic metal oxides, most commonly transition metal oxides (e.g., WO₃, V₂O₅, and the like), electroconductive polymers, such as unsubstituted and substituted polyaniline, polythiophene and polypyrrole, and the like. Examples of suitable electrode materials for use in the electrochromic element are transparent metal oxides, such as ITO, fluorine doped SnO₂, and the like; semi-transparent thin metals (such as Au etc); and conducting polymers, such as poly(3,4-ethylenedioxythiophene)/polystyrene sulfonate (PEDOT/PSS), and like materials. In one embodiment, ion conductors and/or electrolytes may also be employed as components of the electrochromic element in the color tunable light-emitting device. Examples of suitable ion conductors and electrolytes include liquid electrolyte solutions, such as lithium perchlorate in propylene carbonate, and ionic liquids; gel electrolytes comprising a polymeric material (e.g., polyvinyl butyral, polyethylene oxide, polymethyl methacrylate, and polyethylene glycol), a lithium salt (e.g., LiClO₄, LiCF₃SO₃, LiCl, LiPF₆), and a solvent (e.g., propylene carbonate, acetonitrile, ethylene carbonate, and the like); and solid polymeric electrolytes (e.g., cured or crosslinked polyacrylates, polyurethanes, and the like).

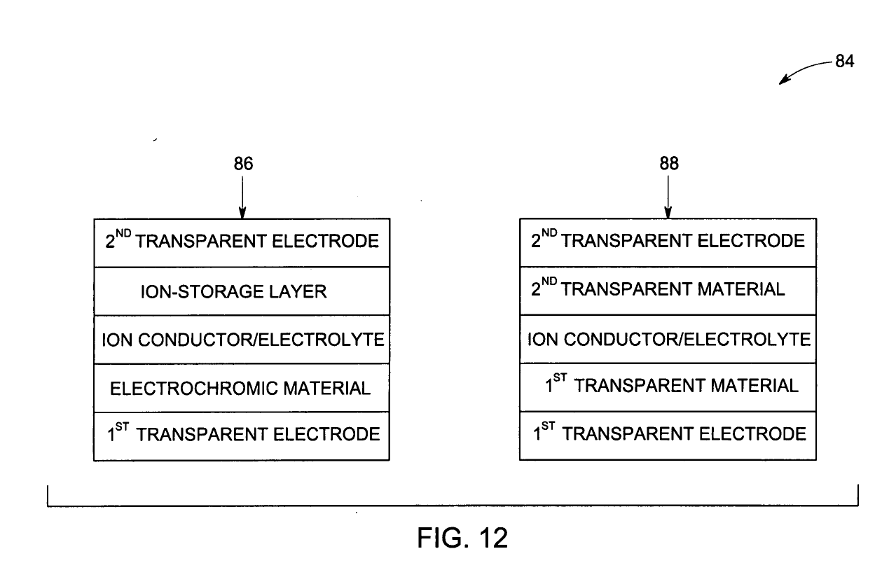

Electrochromic elements are at times herein referred to as electrochromic devices, “ECDs”. Exemplary ECD's (84) are shown in FIG. 12. The ECDs may be “inorganic” ECDs or “organic” ECDs. Inorganic ECDs having the configuration 1 (86, FIG. 12) can be fabricated according to “C. Bechinger et al J. Appl. Phys. 80, pp1226, 1996” and “D. R. Rosseinsky et al., Advanced Materials, 13, pp 783-793, 2001”. In particular, ITO is used as a bottom transparent electrode (1^{st} Transparent Electrode), onto which an electrochromic material (typically comprising a transition metal oxide, such as WO₃), an ion conductor layer (such as MgF₂, or an electrolyte), an ion-storage layer (such as V₂O₅) and a transparent top electrode (2^{nd} Transparent Electrode) (for example a thin metal layer, an ITO layer, or like material) are sequentially deposited. In one embodiment, the change in color and/or transmittance may be controlled by the choice of the electrochromic material employed.

Organic ECDs, having the configuration 2 ((88), FIG. 12) can be fabricated according to “W. Lu, et al, Science, 297, pp983-987, 2002” and “A. A. Argun et al, Adv. Mater. 15, pp1338-1341, 2003”. In a particular embodiment, ITO is used as the bottom transparent electrode, onto which a first organic electrochromic material (not shown in the figure) (such as polythiophene and its derivatives), an ion conductor layer (such as an electrolyte), a second complementary electrochromic material (not shown in the figure) (such as polyaniline), and another transparent top electrode (for example a thin metal layer, an ITO layer, or like material) are sequentially deposited. Alternatively, as disclosed in U.S. Pat. No. 5,124,832 and U.S. Pat. No. 6,136,161, the device assembly can be fabricated by lamination, i.e. forming the device assembly by laminating (1) a first component comprising a substrate, a first transparent conductor (for example an ITO layer, an F doped SnO₂ layer, or like material), a first polymeric electrochromic material (for example polythiophene), a preformed sheet of electrolyte, for example, a gel electrolyte (for example lithium triflate dispersed in a polymer matrix), and (2) a second component comprising a second electrochromic material, an inorganic ion-storage layer (such as TiO₂), and a substrate. The change in color and/or transmittance may be controlled by the choice of electrochromic material employed. For example, red, green, and blue electrochromic polymeric materials may be employed as disclosed by Sonmez et al “G. Sonmez et al, Adv. Mater., V16, pp1905, 2004”.

Inorganic-organic hybrid ECDs, having the configuration 1 ((86), FIG. 12), can be fabricated according to “H. Heuer, et al, Adv. Funct. Mater. V12, pp89-94, 2002”. In particular, the device assembly is formed by joining (1) a first component comprising a substrate, a first transparent electrode (for example an ITO layer, an F doped SnO₂ layer, or like material), a polymeric electrochromic material (for example polythiophene), and a gel electrolyte (for example lithium triflate dispersed in a polymer matrix), with (2) a second component comprising an inorganic ion-storage layer (such as TiO₂), a second transparent electrode, and a substrate. The change in color and/or transmittance may be controlled by the choice of the electrochromic material employed.

Photochromic materials are well known in the art. Examples of suitable photochromic materials include asymmetric photochromic compounds as described in U.S. Pat. No. 6,936,725. A “photochromic protein” as described in U.S. Pat. No. 6,956,984 may also be employed as a photochromic element in the color tunable light-emitting device.

Pyran derivatives as described in U.S. Pat. No. 6,306,316 and German patent 198 20781, may be used as photochromic compounds in the photochromic element of the color tunable light-emitting devices of the instant invention. Specific examples of the pyran derivatives include 3-(4-diphenylaminophenyl)-3-(2-fluorophenyl)-3H-naphtho[2,1-b]pyran, 3-(4-dimethylaminophenyl)-3-(2-fluorophenyl)-3H-naphtho[2,1-b]pyran, 3-(2-fluorophenyl)-3-[4-(N-morpholinyl)phenyl]-3H-naphtho[2,1-b]pyran, 3-(2-fluorophenyl)-3-[4-(N-piperidinyl)phenyl]-3H-naphtho[2,1-b]pyran, 3-(4-dimethylaminophenyl)-6-(N-morpholinyl)-3-phenyl-3H-naphtho[2,1-b]pyran, 6-(N-morpholinyl)-3-[4-(N-morpholinyl)phenyl]-3-phenyl-3H-naphtho[2,1 -b]pyran, 6-(N-morpholinyl)-3-phenyl-3-[4-(N-piperidinyl)phenyl]-3H-naphtho[2,1-b]pyran, and 6-(N-morpholinyl)-3-phenyl-3-[4-(N-pyrrolidinyl)phenyl]-3H-naphtho[2,1-b]pyran, and mixtures of two or more of the foregoing. Photochromic indeno[2,1-f]naphtho[1,2-b]pyrans disclosed in WO 99/15518 and spiro-9-fluoreno[1,2-b]pyrans, disclosed in German patent 19902771 may also serve as components of the photochromic element in the color tunable light-emitting devices of the present invention.

In one embodiment, the photochromic element used in the color tunable light-emitting device of the present invention comprises a cured photochromic polymerizable composition, for example a composition as described in U.S. Pat. No. 6,362,248.

In one embodiment, photochromic 2H-naphtho[1,2-b]pyran compounds that impart grey color, as described in U.S. Pat. No. 6,387,512 may be used in preparing the photochromic element. In an alternate embodiment, one or more of the spiropyran salt compounds disclosed in U.S. Pat. No. 5,708,181 may serve as a component of the photochromic element. Other classes of compounds which may serve as a component of the photochromic are exemplified by azobenzene compounds, thioindigo compounds, dithizone metal complexes, spiropyran compounds, spirooxazine compounds, fulgide compounds, dihydropyrene compounds, spirothiopyran compounds, 1,4-2H-oxazine compounds, triphenylmethane compounds, viologen compounds, naphthopyran compounds, and benzopyran compounds.

A variety of techniques for fabricating photochromic elements are known to those skilled in the art. In one embodiment, the photochromic element is fabricated in a manner as described in U.S. Pat. No. 6,476,103.

In one embodiment, the photochromic substance is used without additional adjuvants. In an alternate embodiment of the present invention, the color changing function and/or the fastness to light may be enhanced by combining the photochromic substance with an adjuvant (also referred to herein as an auxiliary agent) such as one or more high-boiling solvents, plasticizers, synthetic resins, hindered amines, hindered phenols, and the like. These compounds are well known additives for use in combination with photochromic substances and their proportions can be selected from the known ranges. Suitable examples of hindered phenol compounds include, among others, 2,6-di-t-butylphenol, 2,4,6-tri-t-butylphenol, 2,6-di-butyl-p-cresol, 4-hydroxymethyl-2,6-di-t-butylphenol, 2,5-di-t-butylhydroquinone, 2,2′-methylene-(4-ethyl-6-t-butylphenol), 4,4′-butylidene-bis(3-methyl-6-t-butylphenol), and so on. Suitable examples of the hindered amine compounds include, among others, bis(2,2,6,6-tetramethyl-4-piperidinyl)sebacate, bis(1,2,2,6,6-pentamethyl-4-piperidinyl)sebacate, the polycondensate of dimethylsuccinate and 1-(2-hydroxyethyl)-4-hydroxy-2,2,6,6-tetramethylpiperidine, bis(1,2,2,6,6-pentamethyl-4-piperidinyl)-2-(3,5-di-t-butyl-4-hydroxybenzyl)-2-n-butylmalonate, 1-[2-(3-(3,5-di-t-butyl-4-hydroxyphenyl)propionyloxy)ethyl]-4-(3-(3,5-di-t-butyl-4-hydroxyphenyl)propionyloxy)-2,2,6,6-tetramethylpiperidine, 8-benzyl-7,7,9,9-tetramethyl-3-octyl-1,3,8-triazaspiro[4.5]undecane-2,4-di one, tetrakis(2,2,6,6-tetramethyl-4-piperidine)butane carbonate, and Mark LA57, Mark LA62 and Mark LA67 (all the trademarks of Adeka-Argus Chemical Co., Ltd.) which are disclosed in Japanese Unexamined Patent Publication No. 252496/1987.

A wide variety of thermochromic materials known in the art can be used in the thermochromic element in the present invention. Exemplary thermochromic materials containing an acid-responsive chromogenic substance and an acidic substance as disclosed in U.S. Pat. No. 5,431,697 may be used. Acid-responsive chromogenic substances include triphenylmethanephthalide compounds, phthalide compounds, phthalan compounds, acyl-leucomethylene blue compounds, fluoran compounds, triphenylmethane compounds, diphenylmethane compounds, spiropyran compounds, and the like. Suitable specific acid-responsive chromogeneic substances include, but are not limited to, 3,6-dimethoxyfluoran, 3,6-dibutoxyfluoran, 3-diethylamino-6,8-dimethylfluoran, 3-chloro-6-phenylaminofluoran, 3-diethylamino-6-methyl-7-chlorofluoran, 3-diethylamino-7,8-benzofluoran, 2-anilino-3-methyl-6-diethylaminofluoran, 3,3′, 3″-tris(p-dimethylaminophenyl)phthalide, 3,3′-bis(p-dimethylaminophenyl)phthalide, 3-diethylamino-7-phenylaminofluoran, 3,3-bis(p-diethylaminophenyl)-6-dimethylaminophthalide, 3-(4-diethylaminophenyl)-3-(1-ethyl-2-methylindol-3-yl)phthalide, 3-(4-diethylamino-2-methyl)phenyl-3-(1,2-dimethylindol-3-yl)phthalide, and 2′-(2-chloroanilino)-6′-dibutylaminospiro-(phthalido-3,9′-xanthene). Suitable acidic substances include 1,2,3-benzotriazole compounds, phenol compounds, thiourea compounds, oxo-aromatic carboxylic acids, and the like. Specific examples of acidic compounds include 5-butylbenzotriazole, bisbenzotriazole-5-methane, phenol, nonylphenol, bisphenol A, bisphenol F, 2,2′-biphenol, beta-naphthol, 1,5-dihydroxynaphthalene, alkyl p-hydroxybenzoates, phenol resin oligomer, and the like. The thermochromic materials may preferably be used with a solvent. The use of a solvent renders the material responsive to change in temperature with greater sensitivity and definition. Suitable solvents include alcohols, alcohol-acrylonitrile adducts, azomethine compounds, esters, and the like. Among specific examples of the solvent are decyl alcohol, lauryl alcohol, myristyl alcohol, cetyl alcohol, stearyl alcohol, behenyl alcohol, lauryl alcohol-acrylonitrile adduct, myristyl alcohol-acrylonitrile adduct, stearyl alcohol-acrylonitrile adduct, benzylidene-p-toluidine, benzylidene-butylamine, octyl caprate, decyl caprate, myristyl caprylate, decyl laurate, lauryl laurate, myristyl laurate, decyl myristate, lauryl myristate, cetyl myristate, lauryl palmitate, cetyl palmitate, stearyl palmitate, cetyl p-t-butylbenzoate, stearyl 4-methoxybenzoate, dilauryl thiodipropionate, dimyristyl thiodipropionate, stearyl benzoate, benzyl stearate, dibenzyl thiodipropionate, distearyl thiodipropionate, benzyl benzoate, and glycerol trilaurate. It should be understood that the term “thermochromic material” is used herein to mean any and all thermochromic materials including pseudo-thermochromic materials, which show a hysteresis of thermochromism.

Intrinsically thermochromic materials as disclosed in U.S. Pat. No. 5,426,143 may also be used in the thermochromic element in the color tunable light-emitting device. Intrinsically thermochromic materials comprise chromophores which are chemically altered on heating without the need for an external reagent, and which change color in the process. Thermochromic colors including Fast Yellow Gold Orange, Vermillion, Brilliant Rose, Pink, Magenta, Fast Blue, Artic Blue, Brilliant Green, Fast Black, Green Brown and mixtures of the foregoing, as disclosed in U.S. Pat. No. 6,929,136 may be used in the thermochromic element. Rylene dyes as disclosed in U.S. Pat. No. 6,486,319 may also be employed in the thermochromic element. Another exemplary thermochromic material as disclosed in U.S. Pat. No. 4,138,357 comprises a substantially colorless electron donating color-former capable of forming color upon reacting with an electron accepting acid compound and an aromatic hydroxy ester. As disclosed in U.S. Pat. No. 4,028,118 a thermochromic material exhibiting a sharp and reversible metachromation at temperatures within a range of from −40° C. to 80° C., formed from an electron donating chromatic organic compound, a compound containing a phenolic hydroxyl group, a compound selected from the group consisting of higher aliphatic monovalent alcohols and a compound selected from the group consisting of higher aliphatic monovalent acid alcohol esters can also be used as the thermochromic element in the color tunable light-emitting device.

Reversible thermochromic pigments that change color in the presence of diaminoalkane activators as disclosed in U.S. Pat. No. 5,480,482 may also be used as the thermochromic element of the present invention. Suitable dyes that can be employed in making the pigments include but are not limited to 6-(dimethylamino)-3,3-bis(dimethylaminophenyl)-1-(3H)isobenzofuranone (crystal violet lactone); 2′-anilino-6-diethylamino-3-methylfluoran; 2′-dibenzylamino-6′-diethylaminofluoran; 3,3-bis-(1-butyl-2-methyl-1-H-indol-3-yl)-1(3H)-isobenzofuranone; 3-(4-dimethylaminophenyl)-3-[N,N′-bis(4-octylphenyl)amino)phthalide; 2,4,8,10-tetraiodo-3,9-dihydroxy-6-(3′,4′,5′,6′-tetrachlorophenyl-2-phthalido)xanthenone (Rose Bengal lactone); 3,3-bis(4′-hydroxy-3′-methyl-5′-dicarboxymethylamino-methyl)phenyliosbenzofuran-3-one (o-cresolphthalein complexone); 3,3-bis(sodium-3′-sulfonato-4′-hydroxyphenyl)-4,5,6,7-tetrabromoisobenzofuran-3-one (sulfobromonaphthalein sodium salt); 3,3-bis(3′,5′-dibromo-4-hydroxyphenyl)isobenzofuran-3-one (tetrabromophenolphthalein bromocresol green thymolphthalein. These pigments may be used in thermochromic elements capable of modulating an exceptionally wide range of color inputs, thereby providing even greater color control of the light output from the color-tunable light emitting devices of the present invention.

Other reversible thermochromic materials as disclosed in U.S. Pat. No. 5,281,570 comprising an electron donor color-former; a sulfide, sulfoxide or sulfone containing a hydroxy phenyl group; and a chemical compound selected from alcohols, esters, ethers, ketones, carboxylic acids or acid amides, that chromatizes very brightly and in a dense color, generating a change of chromic hue (colored-colorless) within a narrow temperature range and providing a stable thermochromatism on a long term basis can also be employed in the thermochromic element. Alternately a reversible thermochromic composition as provided in U.S. Pat. No. 6,048,387 containing a diazarhodamine lactone derivative as an electron-donating color-developing organic compound, an electron-accepting compound, and a reaction medium for causing a reversible electron exchange reaction between the components in a specified temperature range may be used. This reversible thermochromic composition develops clear reddish color in its colored state, and becomes colorless in its colorless state, and is remarkably free of residual color. Still other reversible thermochromic compounds include bridged phthalides and sulfinate esters as disclosed in U.S. Pat. No. 5,294,375.

Additional thermochromic compositions known in the art can also be employed in the thermochromic element of the color tunable light-emitting devices of the present invention. In one instance, the thermochromic composition comprises an electron donating chromogeneic organic compound, an electron accepting compound and at least one desensitizer selected from among diphenylamine derivatives as disclosed in U.S. Pat. No. 5,350,634 and at least one desensitizer selected from among carbazole derivatives as disclosed in U.S. Pat. No. 5,350,633. Another example of a thermochromic composition as disclosed in U.S. Pat. No. 4,743,398 comprises a colorant in a binder and an activator that causes the thermochromic colorant to change color at a temperature lower than the temperature at which the colorant would undergo a color change in the absence of the activator. In one specific example, the thermochromic colorant is folic acid and the activator is an acid that has a pK of less that 4.2. Yet another suitable thermochromic composition is disclosed in U.S. Pat. No. 4,717,710 which provides a thermochromic composition comprising an electron-donating chromogeneic material, a 1,2,3-triazole compound, a weakly basic, sparingly soluble azomethine or carboxylic acid salt, and an alcohol, amide or ester solvent. Other examples of thermochromic compositions include combinations of at least one color-former and at least one Lewis acid in a polymer mixture as disclosed in U.S. Pat. No. 6,908,505. Such compositions reversibly change appearance from substantially transparent to substantially non-transparent above a lower critical solution temperature. Another exemplary composition is disclosed in U.S. Pat. No. 4,620,941 and comprises at least one electron-donating organic chromogenic compound, at least one compound serving as a color developing material and selected from thiourea and derivatives thereof, guanidine and derivatives thereof, benzothiazole, and benxothiazolyl derivatives, and at least one compound serving as a desensitizer selected from the group consisting of alcohols, esters, ketones, ethers, acid amides, carboxylic acids, and hydrocarbons.

The reflective elements that can be employed in certain embodiments include but are not limited to mirrors and aluminum film. Mirrors may typically include highly reflective metallic foils, or a metal film on a glass or a plastic substrate.

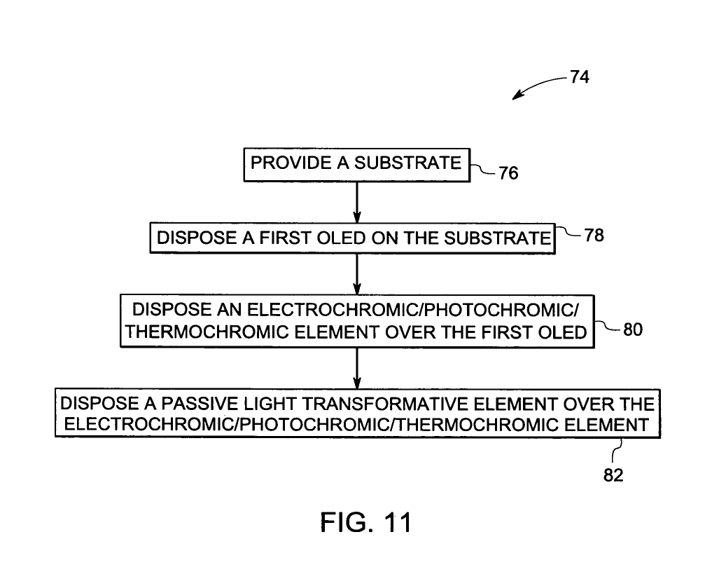

FIG. 11 is a flow chart illustrating an exemplary process (74) of fabricating a color tunable light-emitting device according to aspects of the present invention. Process (74) begins with providing a substrate (76), which is, in one embodiment, a glass substrate. (In the discussion of FIG. 11, FIG. 2 serves as a useful point of reference). In FIG. 2 the first OLED is pictured as comprising elements (24) (a first substrate), (26) (a first electrode), (28) (a first electroluminescent layer), and (30) (a second electrode)). In the next step, (78), a first OLED is disposed upon the substrate. In a following step (80), an active light transformative element (e.g. an electrochromic element, a photochromic element, or a thermochromic element) is disposed on the first OLED (see FIG. 2). In a following step (82), a passive light transformative element is disposed over the active light transformative element (see FIG. 2).

Depositing or disposing the various layers comprising the color-tunable light-emitting devices of the present invention may be carried out using known techniques such as spin coating, dip coating, reverse roll coating, wire-wound or Mayer rod coating, direct and offset gravure coating, slot die coating, blade coating, hot melt coating, curtain coating, knife over roll coating, extrusion, air knife coating, spray, rotary screen coating, multilayer slide coating, coextrusion, meniscus coating, comma and microgravure coating, lithographic processes, langmuir processes, flash evaporation, vapor deposition, plasma-enhanced chemical-vapor deposition (“PECVD”), radio-frequency plasma-enhanced chemical-vapor deposition (“RFPECVD”), expanding thermal-plasma chemical-vapor deposition (“ETPCVD”), electron-cyclotron-resonance plasma-enhanced chemical-vapor deposition (ECRPECVD”), inductively coupled plasma-enhanced chemical-vapor deposition (“ICPECVD”), sputtering techniques (including, reactive sputtering), like techniques, and combinations thereof.

Without further elaboration, it is believed that one skilled in the art can, using the description herein, utilize the present invention to its fullest extent. The following examples are included to provide additional guidance to those skilled in the art in practicing the claimed invention. The examples provided are merely representative of the work that contributes to the teaching of the present application. Accordingly, these examples are not intended to limit the invention, as defined in the appended claims, in any manner.

### EXAMPLES

### Example 1

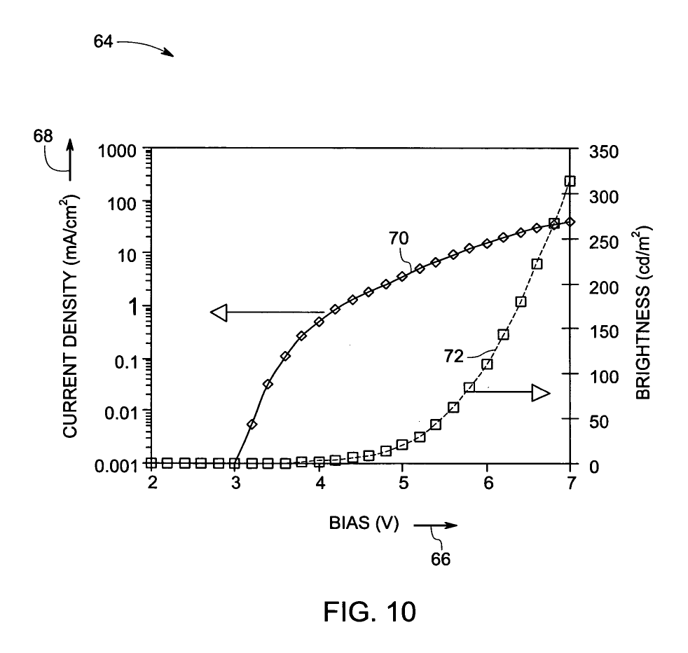

An OLED was fabricated as follows. A glass substrate that was precoated with ITO was purchased from Applied Films, Longmont, Colo., and then cleaned with ultraviolet radiation and ozone. A layer of poly(3,4ethylenedioxythiophene)/polystyrene sulfonate (PEDOT/PSS) having a thickness of about 60 nm was deposited by spin coating on the ITO side of the cleaned ITO-coated glass, and baked for one hour at about 170° C. in ambient atmosphere. The coated piece was then transferred to an argon filled glovebox nominally containing less than 1 ppm of oxygen and moisture. A layer of a blue light-emitting polymer (ADS329BE—[poly(9,9-dioctylfluoenyl-2,7-diyl)—end capped with N,N-Bis(4-methylphenyl)-aniline] obtained from American Dye Sources, Inc, Canada) having a thickness of about 80 nm was deposited by spin coating on the PEDOT/PSS layer. A layer of NaF having a thickness of about 4 nm was vapor deposited, at a vacuum of about 2×10⁻⁶ mm Hg, on the polymer layer. Then a layer of aluminum having a thickness of about 110 nm was similarly vapor deposited on the NaF layer. Then the entire multilayer ensemble was encapsulated with a glass slide and sealed with epoxy. Brightness and current density of the OLED as a function of bias voltage was measured and the results are as shown in FIG. 10. The curve (70) illustrates the relationship between the voltage bias and the current density observed. The curve (72) illustrates the relationship between the voltage bias and the brightness of the OLED observed.

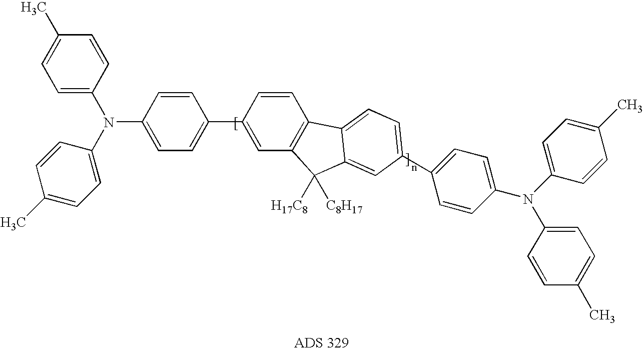

### Examples 2-3

A color tunable light-emitting device is fabricated as follows. (FIG. 2 illustrates a representative color tunable light-emitting device comprising a mirror. FIG. 4 illustrates a representative color tunable light-emitting device but does not illustrate the inclusion of a mirror As described in Example 1 above a blue light-emitting OLED is prepared. An electrochromic element is prepared following the procedure of Step 1 of Example 1 but replacing the LEP with an electrochromic material, heptyl viologen bromide. The electrochromic element is then sandwiched between the OLED and a red phosphor film. A mirror is then disposed over the red phosphor wherein the reflective surface of the mirror is in contact with the red phosphor. This assembly comprising the OLED, the electrochromic element, the red phosphor and the mirror is then encapsulated using a glass slide sealed with Norland Optical Adhesive 68, provision having been made for the OLED and the electrochemical elements to be connected to a single power source as shown in FIG. 2. The final perceived color or perceived light emerging from the color-tunable light-emitting device is a combination of the light modulated by the voltage bias applied across the OLED and the electrochromic element, the light emitted from the red phosphor and the light reflected by the mirror. When there is no mirror as depicted in FIG. 4, the perceived light or perceived color emerging from the color-tunable light-emitting device is a combination of the light modulated by the voltage bias applied across the OLED and the electrochromic element and the light emitted from the red phosphor.

### Examples 4-5

A color tunable light-emitting device is fabricated as follows. (FIG. 5 —illustrates a representative color tunable light-emitting device comprising a mirror. FIG. 6 illustrates a representative color tunable light-emitting device but does not illustrate the inclusion of a mirror) ). As described in Example 1 above a blue light-emitting OLED is prepared. An electrochromic element is prepared following the procedure of Step 1 of Example 1 but replacing the LEP with an electrochromic material, heptyl viologen bromide. The electrochromic element is then sandwiched between the OLED and a green phosphor film. A second electrochromic element, prepared as described above, is then disposed over the green phosphor film and then a red phosphor film is disposed over the second electrochromic element. A mirror is then disposed over the red phosphor film wherein the reflective surface of the mirror is in contact with the red phosphor. The entire assembly comprising the OLED, the first electrochromic element, the green phosphor, the second electrochromic element, the red phosphor and the mirror, is then encapsulated using a glass slide sealed with Norland Optical Adhesive 68, provision having been made for the OLED and the electrochemical elements to be connected to one or more power sources. The final perceived color or perceived light emerging from the color-tunable light-emitting device is a combination of the light modulated by the voltage bias applied across the OLED and the two electrochromic elements, the light emitted from the red phosphor and green phosphor and the light reflected by the mirror.

While only certain features of the invention have been illustrated and described herein, many modifications and changes will occur to those skilled in the art. It is, therefore, to be understood that the appended claims are intended to cover all such modifications and changes as fall within the true spirit of the invention.

1. A color tunable light-emitting device comprising:
i. a first light-emitting element;
ii. a passive light transformative element;
iii. an active light transformative element selected from the group consisting of electrochromic elements, photochromic elements, and thermochromic elements, said active light transformative element being disposed between said first light-emitting element and said passive light transformative element; and
iv. at least one light transmissive element.

2. The color tunable light-emitting device according to claim 1, wherein the first light-emitting element is an organic light-emitting device comprising
a. a first electrode;
b. a second electrode; and
c. an electroluminescent layer disposed between the first electrode and the second electrode,
wherein the first electrode and the second electrode are “operably coupled” to at least one tunable voltage source.

3. The color tunable light-emitting device according to claim 2, wherein the electroluminescent layer comprises an organic polymer.

4. The color tunable light-emitting device according to claim 3, wherein the organic polymer comprises at least one electroluminescent polymer selected from the group consisting of polyfluorene, poly(phenylene vinylene), poly(vinyl carbazole), and their derivatives.

5. The color tunable light-emitting device according to claim 2, wherein the electroluminescent layer comprises an organometallic compound.

6. The color tunable light-emitting device according to claim 1, wherein the at least one passive light transformative element comprises a photoluminescent material.

7. The color tunable light-emitting device according to claim 1, wherein the at least one passive light transformative element comprises a phosphor.

8. The color tunable light-emitting device according to claim 1, wherein the at least one passive light transformative element is a color filter.

9. The color tunable light-emitting device according to claim 1, wherein said active light transformative element is an electrochromic element.

10. The color tunable light-emitting device according to claim 9, wherein the electrochromic element comprises a
a. a first electrode;
b. a second electrode; and
c. an electrochromophore layer disposed between the first electrode and the second electrode,
wherein the first electrode and the second electrode are “operably coupled” to at least one tunable voltage source.

11. The color tunable light-emitting device according to claim 10, wherein the electrochromophore comprises a transition metal compound.

12. The color tunable light-emitting device according to claim 10, wherein the electrochromophore comprises a polymeric electrochromic material.

13. The color tunable light-emitting device according to claim 1, said device further comprising at least one organic light-emitting element in addition to the first light-emitting element.

14. The color tunable light-emitting device according to claim 1, wherein the light transmissive element is a transparent substrate.

15. The color tunable light-emitting device according to claim 1, wherein the at least one light transmissive element comprises glass.

16. The color tunable light-emitting device according to claim 1, wherein the at least one light transmissive element comprises at least one organic polymer.

17. The color tunable light-emitting device according to claim 1, further comprising a reflective element.

18. The color tunable light-emitting device according to claim 17, wherein the reflective element comprises a mirror.

19. The color tunable light-emitting device according to claim 17, wherein the reflective element comprises a reflecting electrode.

20. The color tunable light-emitting device according to claim 2, wherein the first light emitting element further comprises a hole transport layer, a hole injection layer, an electron transport layer, an electron injection layer, or any combination thereof.

21. A color tunable light-emitting device comprising:
i. an organic light emitting device comprising a first electrode, a second electrode, and an electroluminescent layer disposed between the first electrode and the second electrode;
ii. a passive light transformative element;
iii. an electrochromic element disposed between said first light-emitting element and said passive light transformative element; and
iv. at least one light transmissive element.

22. A color tunable light-emitting device comprising:
i. an organic light emitting device comprising a first electrode, a second electrode, and an electroluminescent layer disposed between the first electrode and the second electrode;
ii. a passive light transformative element;
iii. a photochromic element disposed between said first light-emitting element and said passive light transformative element; and
iv. at least one light transmissive element.

23. The color tunable light-emitting device according to claim 22, wherein the photochromic element is operably coupled with at least one external intensity tunable light source.

24. A color tunable light-emitting device comprising:
i. an organic light emitting device comprising a first electrode, a second electrode, and an electroluminescent layer disposed between the first electrode and the second electrode;
ii. a passive light transformative element;
iii. a thermochromic element disposed between said first light-emitting element and said passive light transformative element; and
iv. at least one light transmissive element.

25. The color tunable light-emitting device according to claim 24, wherein the thermochromic element comprises a thermochromic compound contained in a base material.

26. The color tunable light-emitting device according to claim 24, wherein the thermochromic element is operably coupled with at least one external temperature tunable heat source.
